(19) United States
(12) Patent Application Publication
(10) Pub. No.: US 2001/0013652 A1
(43) Pub. Date: Aug. 16, 2001

(54) SEMICONDUCTOR DEVICE FREE FROM SHORT-CIRCUIT BETWEEN BUMP ELECTRODES AND SEPARATION FROM CIRCUIT BOARD AND PROCESS OF FABRICATION THEREOF

(76) Inventors: SHIGEHARU HINO, SHIGA (JP); GOROU IKEGAMI, SHIGA (JP)

Correspondence Address: HELFGOTT & KARAS, 60TH FLOOR, EMPIRE STATE BUILDING, NEW YORK, NY, 10118

(21) Appl. No.: 09/052,287

(22) Filed: Mar. 31, 1998

(30) Foreign Application Priority Data
Mar. 31, 1997 (JP) 978736

(51) Int. Cl. H01L 21/44; H01L 23/48; H01L 23/52; H01L 29/40

(52) U.S. Cl. 257/738; 257/737; 438/613; 438/617

(57) ABSTRACT

Bump electrodes are formed on a semiconductor pellet by tearing off conductive wires so as to expose fresh metal, and pad electrodes on a circuit board are cleared by exposing them to an ionic beam or an atomic beam; when the bump electrodes are bonded to the pad electrodes, bump electrodes are heated to a certain temperature lower than the melting point of the metal, and are pressed against the pad electrodes, thereby preventing the bump electrodes from undesirable short-circuit.

### FIELD OF THE INVENTION

This invention relates to a semiconductor device panel and, more particularly, to a semiconductor device free from short-circuit between bump electrodes and separation from a printed circuit board and a process of fabrication thereof.

### DESCRIPTION OF THE RELATED ART

An electronic component has become multifunctional, and, accordingly, has been increased in integration density. On the other hand, there is a continuous demand for scale-down. One of the approaches is to directly mount semiconductor bare chips on a printed circuit board without sealing it in synthetic resin.

A typical example is disclosed in Japanese Patent Publication of Unexamincd Application No. 3-171643. FIG. 1 illustrates a semiconductor pellet 1 mounted on a printed circuit board 2 through the prior art process disclosed in the Japanese Patent Publication of Unexamined Application.

Though not shown in FIG. 1, an aluminum layer is formed on a semiconductor substrate la, and the aluminum layer is overlain by an underlying layer of composite metal containing chromium, copper and gold. Bump electrodes 1b of eutectic solder are formed on the underlying layer. When the semiconductor substrate 1a is heated in non-oxidizing atmosphere, the eutectic solder is melted, and the surface tension forms the melted eutectic solder into spherical configuration. The melted eutectic solder is quenched, and the spherical eutectic solder pieces are formed into the bump electrodes 1b through the eutectic phenomenon.

On the other hand, the printed circuit board 2 has pad electrodes 2a on an insulating plate 2b. The semiconductor pellet 1 is opposed to the printed circuit board 2, and the bump electrodes 1b are bonded to the pad electrodes 2a through the prior art process shown in FIG. 2A to 2C.

First, the semiconductor pellet 1 and the printed circuit board 2 are prepared as shown in FIG. 2A. The semiconductor pellet 1 and the printed circuit board 2 are placed in a surface activation chamber 3. Vacuum is created in the surface activation chamber 3, and argon gas is introduced thereinto. Though not shown in the drawings, a source gun is provided in the surface activation chamber 3, and produces an atomic beam 3a from the argon gas. The atomic beam 3a is radiated to the semiconductor pellet 1 and the printed circuit board 2, and removes the natural oxide films and contaminants from the bump electrodes 1b and the pad electrodes 2a. Then, the bump electrodes 1b and the pad electrodes 2a are cleaned, and, accordingly, the surfaces thereof are activated.

Upon completion of the surface activation, the semiconductor pellet 1 and the printed circuit board 2 are taken out from the surface activation chamber 3, and are conveyed into a bonding chamber 4. Non-oxidizing ambience is created in the bonding chamber 4. The semiconductor pellet 1 is inverted so as to oppose the bump electrodes 1b to the pad electrodes 2a. The bump electrodes 1b are brought into contact with the pad electrodes 2a, and the bump electrodes 1b are pressed against the pad electrodes 2a.

The bump electrodes 1b are firstly heated to certain temperature lower than the fusing temperature of the solder. Then, the bump electrodes 1b are temporarily connected to the pad electrodes 2a through the plastic deformation. After the temporary connection, the bump electrodes 1b are heated over the fusing temperature, and are bonded to the pad electrodes 2a. Thus, the semiconductor pellet 1 is mounted on the printed circuit board 2. The resultant structure is cooled, and is taken out from the bonding chamber 4. The resultant structure or the prior art semiconductor device has the semiconductor pellet 1 mounted on the printed circuit board as shown in FIG. 1.

The prior art semiconductor device and the prior art process encounter the following problems. While the bump electrodes 1b are being heated under the pressure against the pad electrodes 2a, the melted eutectic solder sidewardly extends from the associated pad electrodes 2a, and is liable to be merged. This results in undesirable short-circuit. Even if the melted eutectic solder is not merged, the bump electrodes 1b become close to each other, and allow discharge to take place. Thus, the first problem inherent in the prior art semiconductor device is the short-circuit or low discharging voltage between the bump electrodes 1b.

Another problem is undesirable separation between the semiconductor pellet 1 and the printed circuit board 2 due to weak bonding strength between the bump electrodes 1b and the pad electrodes 2a. Especially, when the printed circuit board 2 is installed in environment where temperature is frequently changed, cracks undesirably take place in the boundary between the bump electrodes 1b and the pad electrodes 2a, and the semiconductor pellet 1 is much liable to be separated from the printed circuit board 2.

The first problem inherent in the prior art process is poor manipulability. The semiconductor pellet 1 is mounted on the printed circuit board 2 in the non-oxidizing atmosphere. Even if the bump electrodes 1b are offset from the pad electrodes 2a during the temporary connection, the correction is not easy, because the correction should be carried out without breakage of the non-oxidizing atmosphere.

Another problem inherent in the prior art process is high production cost of the semiconductor integrated circuit device. The surface activation chamber 3 is large enough to accommodate the semiconductor pellets 1 and the printed circuit boards 2, and the bonding chamber 4 is wide, because the various mechanisms are installed therein. The wide surface activation chamber 3 consumes a large amount of argon gas, and the wide bonding chamber 4 consumes a large amount of non-oxidizing gas. For this reason, the large amount of gas increases thc cost.

### SUMMARY OF THE INVENTION

It is therefore an important object of the present invention to provide a semiconductor device, which is free from the short-circuit, the low discharging voltage and the separation.

It is also an important object of the present invention to provide a process for fabricating a semiconductor device, which is improved in the manipulability and the process cost.

In accordance with one aspect of the present invention, there is provided a semiconductor device comprising a semiconductor pellet including a semiconductor substrate and bump electrodes projecting from a major surface of the semiconductor substrate and formed of first material, a circuit board including a insulating substrate, a conductive pattern formed on the insulating substrate and pad electrodes laminated on certain areas of the conductive pattern and having a layer of second material and intermediate layers formed of alloy between the first material and the second material and bonding the bump electrodes to the pad electrodes.

In accordance with another aspect of the present invention, there is provided a process for fabricating a semiconductor device comprising the steps of a) preparing a semiconductor pellet including bump electrodes of first material and a circuit board including a conductive pattern and pad electrodes laminated on certain areas of the conductive pattern and having layers of second material, the bump electrodes being torn off from a conductive wire so as to expose fresh first material, the pad electrodes being subjected to one of an ion radiation and an atom radiation so as to remove contaminants therefrom, b) aligning the bump electrodes with the pad electrodes, respectively, and c) pressing the bump electrodes against the pad electrodes under application of heat so as to bond the bump electrodes with the pad electrodes.

### BRIFF DESCRIPTION OF THE DRAWINGS

The features and advantages of the semiconductor device and the process will be more clearly understood from the following description taken in conjunction with the accompanying drawings in which:

FIG. 1 is a cross sectional view showing the semiconductor bare chip mounted on the printed circuit board;

FIGS. 2A to 2C are schematic views showing the prior art process of fabricating a semiconductor integrated circuit device disclosed in Japanese Patent Publication of Unexamined Application No. 3-171643;

FIG. 3 is a cross sectional view showing the structure of a semiconductor device according to the present invention;

FIGS. 4A to 4D are cross sectional views showing a process for fabricating the semiconductor device shown in FIG. 3; and

FIG. 5 is a cross sectional view showing a bump electrode formed on a semiconductor substrate.

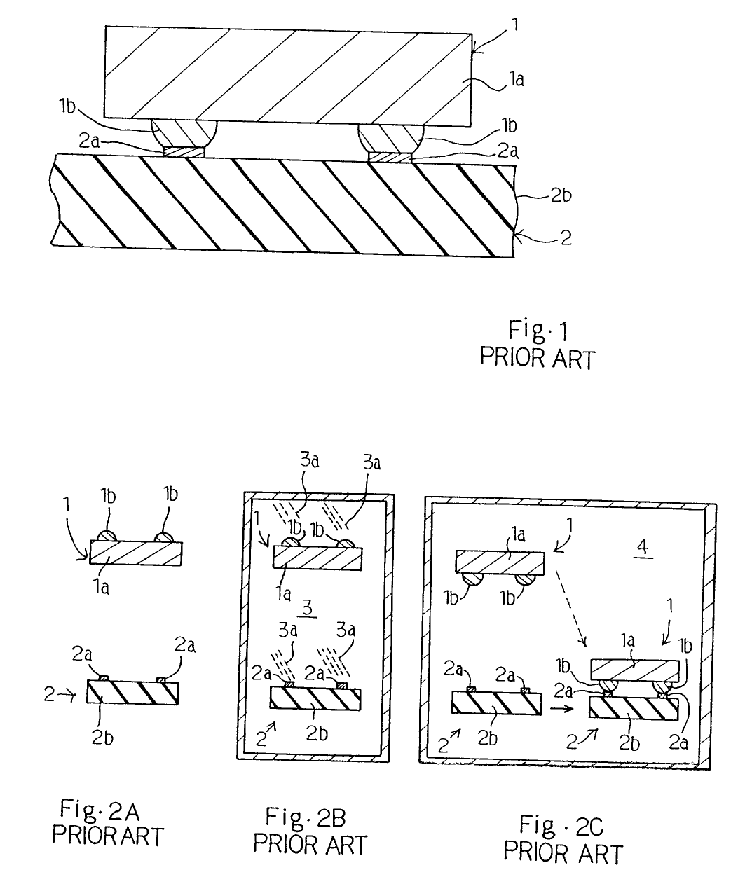

### DESCRIPTION OF THF PRFFFRRFD EMBODIMENT

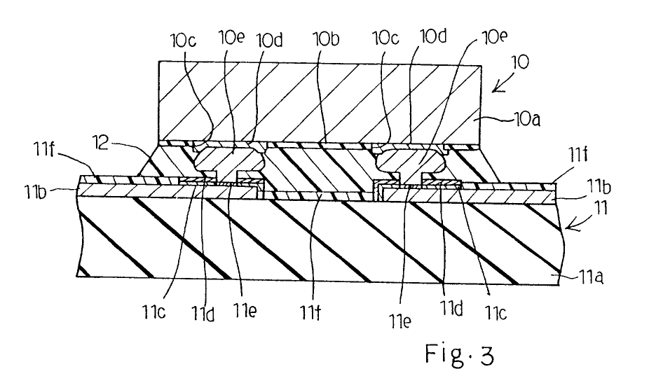

Referring to FIG. 3 of the drawings, a semiconductor device embodying the present invention largely comprises a semiconductor pellet 10, a circuit board 11 and adhesive synthetic resin 12 filling gap between the semiconductor pellet 10 and the circuit board 11.

The semiconductor pellet 10 includes a semiconductor substrate 10a and an insulating layer 10b. A large number of circuit components (not shown) are fabricated on the semiconductor substrate 10a, and are selectively connected through conductive wirings (not shown). The circuit components and the conductive wirings form an integrated circuit. The conductive wirings are covered with the insulating layer 10b, and the insulating layer 10b prevents the integrated circuit from contamination. Contact windows 10c are formed in the insulating layer 10b, and the conductive wirings are exposed to the contact windows 10c. Aluminum pads 10d are formed in the contact windows 10c, and the aluminum pads 10d provide appropriate resistance against the electric current.

The semiconductor pellet 10 further includes bump electrodes 10e attached to the aluminum pads 10d, rcspectively. In this instance, the bump electrodes 10e are formed of gold. The bump electrodes 10e are formed on the aluminum pads 10d as will be described hereinlater.

The circuit board 11 includes an insulating substrate 11a and a conductive pattern 11b of copper formed on a major surface of the insulating substrate 11a. Predetermined areas of the conductive pattern 11b are respectively covered with hard metal films 11c, which in turn are covered with gold films 11d, respectively. The hard metal films 11c may be formed of nickel. Each hard metal film 11c and gold form a gold-nickel alloy layer 11e therebetween, and each hard metal layer 11c and each gold layer 11d as a whole constitute a pad electrode 11e′. The remaining surface of the conductive pattern 11b and the remaining surface of the insulating substrate 11a are covered with a resist layer 11f.

The bump electrodes 10e are respectively bonded to the pad electrode 11e′, and the integrated circuit is electrically connected through the bump electrodes 10e and the pad electrodes 11e′ to the conductive pattern 11b. The adhesive synthetic resin 12 fills the gap between the lower surface of the semiconductor pellet 10 and the circuit board 11. The bonding force between the bump electrodes 10e and the pad electrodes 11e′ and the adhesion of the adhesive synthetic resin 12 fix the semiconductor pellet 10 to the circuit board 11.

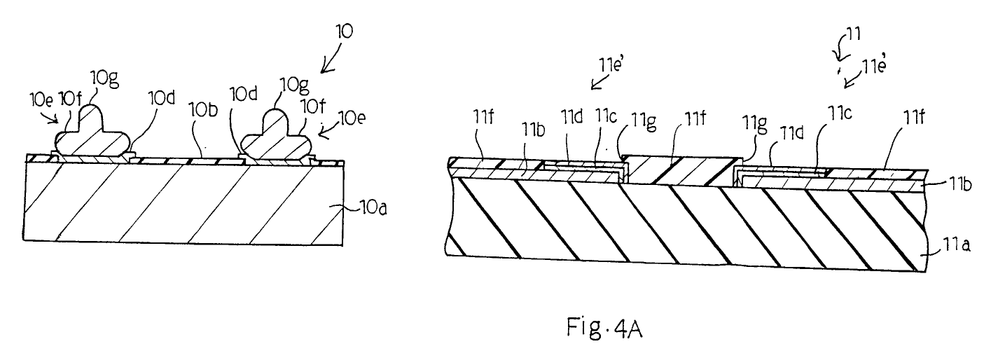

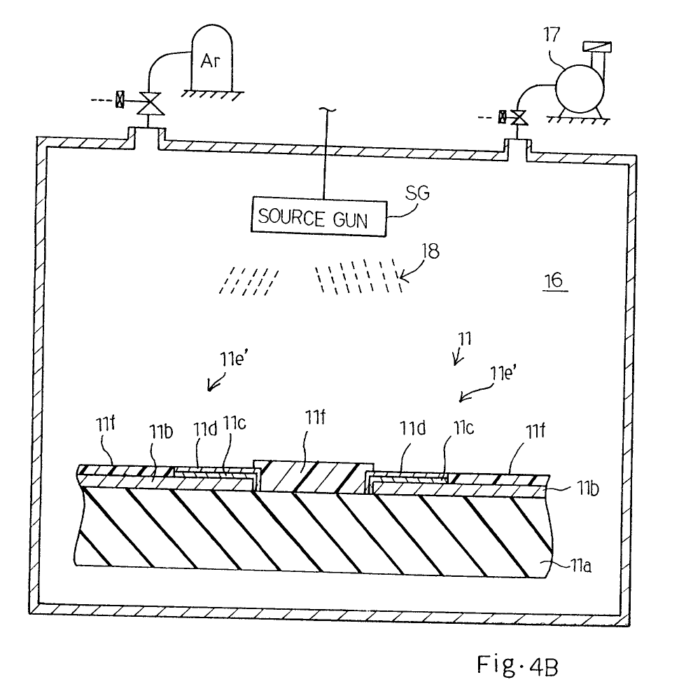

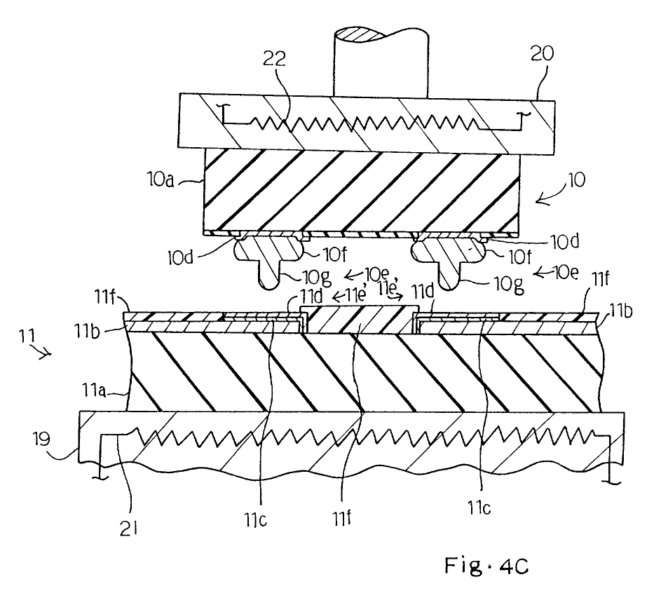

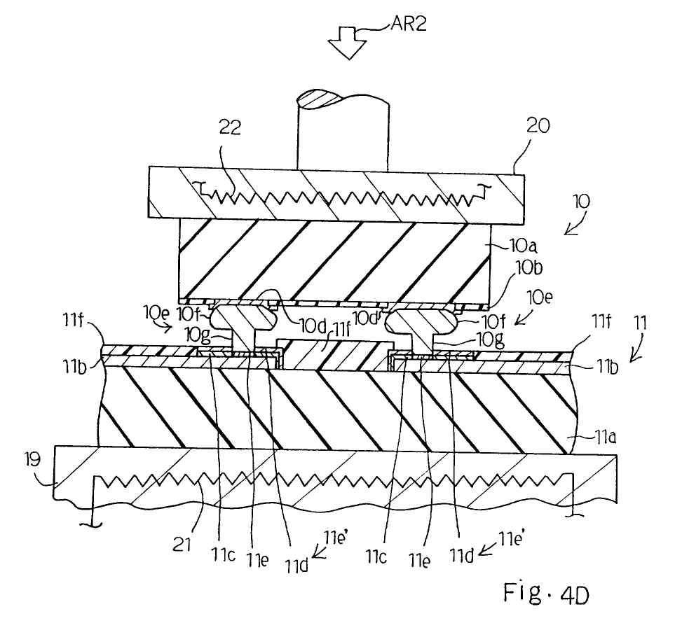

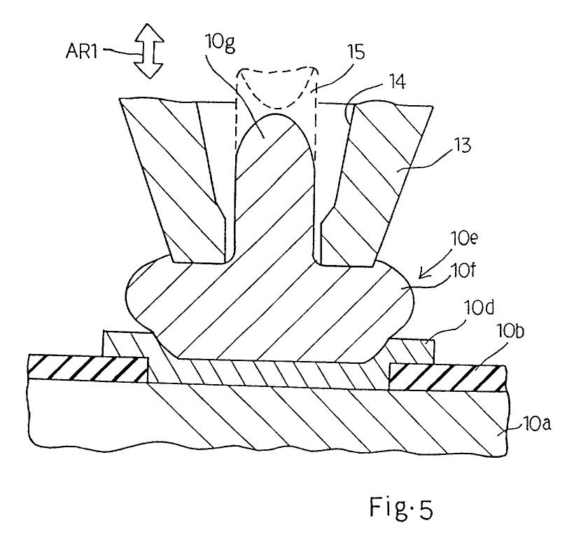

The semiconductor device shown in FIG. 3 is fabricated as follows. Figures 4A to 4D illustrate a process for fabricating the semiconductor device shown in FIG. 3. The process starts with preparation of the semiconductor pellet 10 and the circuit board 11 as shown in FIG. 4A. A person skilled in the art well knows how the integrated circuit is fabricated on a semiconductor wafer and how the semiconductor wafer is separated into the semiconductor pellet 10, and description is focused on how the bump electrodes 10e are formed with reference to FIG. 5.

FIG. 5 illustrates one of the bump electrodes 10e just formed on the aluminum pad 10d. In detail, the semiconductor substrate 10a is conveyed to a kind of ball bonder, and the aluminum pad 10d is placed under a capillary 13. The capillary 13 is reciprocally movable in a direction indicated by arrow AR1, and a through-hole 14 is formed in the capillary 13. A conductive metal wire 15 passes through the through-hole 14, and the leading end of the conductive metal wire 15 is fused so as to form a ball.

The capillary 13 is downwardly moved, and presses the ball against the aluminum pad 10d. While the capillary 13 is pressing the ball against the aluminum pad 10d, ultrasonic vibrations are applied to the ball. The ball is crushed, and is formed into a contact portion 10f of the bump electrode 10e. The contact portion 10f is bonded to the aluminum pad 10d. After the bonding, the capillary 13 is lifted, and the conductive metal wire 15 is strongly pulled. Then, the conductive metal wire 15 is cut, and a tail portion 10g is left on the contact portion 10f as shown in FIG. 5. Fresh metal is exposed to the tail portion 10g, and natural oxide is not grown on the exposed surface. For this reason, any cleaning process is not required for the bump electrodes 10e. The semiconductor pellet 10 is stored in non-oxidizing ambience.

The conductive metal wiring 15 is formed of metal directly bonded to the aluminum pad 10d. In this instance, the conductive metal wiring 15 is formed of gold, and the diameter is 25 microns. The contact portion 10f is 80 microns in diameter and 25 microns in height. The tail portion 10g is like a paraboloid of revolution, and is 75 microns in height from the aluminum pad 10d and 25 microns in diameter at the boundary to the contact portion 10f.

Turning back to FIG. 4A, the circuit board 11 is fabricated as follows. A copper foil of 18 microns thick is laminated on the major surface of the insulating substrate 11a, and is selectively etched away so as to form it into the conductive pattern 11b. The conductive pattern 11b and the insulating substrate 11a are covered with resist material, and the resist material layer is selectively removed so as to form windows 11g in the resist layer 11f. The predetermined areas of the conductive pattern 11b are exposed to the windows 11g, and are plated with hard metal such as, for example, nickel. In this way, the predetermined areas are firstly covered with the hard metal films 11c. Subsequently, the gold films 11d are laminated on the hard metal films 11c, respectively so as to form the pad electrodes 11e′. The hard metal films 11c are 3 microns to 5 microns thick, and the gold films 11d are 0.03 micron to 0.05 micron thick.

Subsequently, the circuit board 11 is placed in a chamber 16 as shown in FIG. 4B, and a vacuum pump 17 evacuates the chamber. The chamber 16 is not so wide as the surface activation chamber 3, because only the circuit board 11 is accommodated therein. Argon gas is introduced into the chamber 16, and a source gun SG produces atomic beam or ionic beam 18 from the argon gas. The atomic beam or the ionic beam 18 is radiated onto the gold films 11d, and slightly removes a surface portion from the gold film 11d. As a result, contaminant is also removed from the gold films 11d, and the gold films 11d are cleaned. The circuit board 11 is stored in non-oxidizing ambience.

The circuit board 11 is placed from the non-oxidizing ambience onto a supporting table 19, and a vacuum pad 20 moves the semiconductor pellet 10 from the non-oxidizing ambience over the circuit board 11 as shown in figure 4C. The vacuum pad 20 and the supporting table 19 are operating in the atmosphere. The bump electrodes 10e are aligned with the pad electrodes 11e′. Heater units 21/22 heats the supporting table 19 and the vacuum pad 20, and the bump electrodes 10e and the pad electrodes 11e′ are heated to 150 degrees to 300 degrees in centigrade and 60 degrees to 120 degrees in centigrade, respectively.

The vacuum pad 20 is downwardly moved as indicated by arrow AR2 in FIG. 4D, and presses the bump electrodes 10e against the gold films 11d. A certain load between 20 grams and 30 grams is exerted on each bump electrode 10e. The bump electrodes 10c are plastically deformed, and penetrate through the gold films 11d. The bump electrodes 10e are brought into contact with the nickel films 11c, and the vacuum pad 20 continuously presses the bump electrodes 10e for 10 seconds to 150 seconds. The gold for the bump electrodes 10e is alloyed with the nickel, and the gold-nickel alloy strongly bonds the bump electrodes 10e to thc nickel films 11c. This is because of the fact that the tail portion 10g is formed of the fresh metal without oxide and contaminant and that the contaminant is removed from the gold films 11d through the atomic radiation or the ionic radiation. The bump electrodes 10e are never melted with heat, and, accordingly, melted metal does not flow out from the pad electrode 11e′. This results in that any short-circuit does not take place between the bump electrodes 10e. In this way, the flip chip bonding structure is obtained.

The vacuum pad 20 is lifted, and the semiconductor pellet 10 is conveyed together with the circuit board 11. Adhesive synthetic resin is injected into the gap between the semiconductor pellet 10 and the circuit board 11, and forms the adhesive synthetic resin layer 12 as shown in FIG. 3. The adhesive synthetic resin layer 12 increases the bonding strength between the semiconductor pellet 10 and the circuit board 11.

The present inventors evaluated the process according to the present invention. First, the present inventors forcibly peeled off the semiconductor pellet 10 from the circuit board 11. The nickel films 11c were separated from the conductive pattern lib, and the nickel films were still strongly bonded to the bump electrodes 10e.

The present inventors exposed the boundary between the bump electrode 10e and the nickel film lc, and the material at the boundary was analyzed by using an Auger electron spectroscopy. The material was gold-nickel alloy.

As will be appreciated from the foregoing description, the semiconductor device is free from short-circuit between the bump electrodes 10e, because the bump electrodes 10e are bonded to the conductive pattern 11b without heating over the melting point. Moreover, the gold-nickel alloy is produced during the bonding stage, and the bump electrodes 10e are strongly bonded to the nickel films 11c. For this reason, even if the semiconductor device is installed in the ambience where the ambience temperature is frequently changed, the semiconductor pellet 10 is never separated from the circuit board 11. The adhesive synthetic resin layer 12 increases the bonding strength between the semiconductor pellet 10 and the circuit board 11.

The process cost is reduced rather than the prior art process. Only the gold films 11d are subjected to the atomic milling or an ionic milling. The chamber 16 is narrower than the surface activation chamber 3, and the consumption of argon gas is less than that of the prior art process. The bonding step is carried out in the atmosphere. Even if the bump electrodes 10e are mis-aligned with the god films 11d, an operator can easily correct the position. Thus, the manipulability is improved.

Although a particular embodiment of the present invention has been shown and described, it will be obvious to those skilled in the art that various changes and modifications may be made without departing from the spirit and scope of the present invention.

For example, the adhesive synthetic resin layer 12 may be dcleted from the semiconductor device according to the present invention.

The bump electrodes 10e may be formed before separation of a semiconductor wafer into the pellets.

The conductive metal wire 15 may be formed of copper. In this instance, the a protective layer may be formed on the aluminum pad 10d so as to prevent the aluminum and copper from mutual diffusion.

The insulating substrate 11a may be rigid or flexible. If a flexible film is used for the circuit board 11, the flexible film is resiliently deformed during the bonding step. After the bonding step, the flexible film is recovered to the previous configuration, and urges the pad electrodes 11e′ toward the bump electrodes 10e.

While the bump electrodes 10e are being pressed against the gold/ nickel films 11c/11d, ultrasonic vibrations may be applied to the boundary between the bump electrodes 10e and the gold/nickel films 11c/11d. The ultrasonic vibrations remove contaminant from the boundary, and allow the heater unit 22 to decrease the temperature of the semiconductor pellet 10. The ultrasonic vibrations further decrease time consumed for the bonding. If the tail portions 10g are regulated to a target height before the bonding, the application of ultrasonic vibrations is more effective.

The hard metal is defined as “conductive metal alloyed with metal for bump electrodes and harder than the metal for the bump electrodes”. From this aspect, titanium, chromium, palladium and alloy thereof may be used as the hard metal.

What is claimed is:

1. A semiconductor device comprising
a semiconductor pellet including a semiconductor substrate and bump electrodes projecting from a major surface of said semiconductor substrate and formed of first material,
a circuit board including
an insulating substrate,
a conductive pattern formed on said insulating substrate and
pad electrodes laminated on certain areas of said conductive pattern and having a layer of second material, and
intermediate layers formed of alloy between said first material and said second material and bonding said bump electrodes to said pad electrodes.

2. The semiconductor device as set forth in claim 1, in which said first material and said second material are gold and nickel, respectively.

3. The semiconductor device as set forth in claim 1, further comprising an adhesive synthetic resin layer inserted between said semiconductor pellet and said circuit board so as to enhance the adhesion therebetween.

4. A process for fabricating a semiconductor device, comprising the steps of:
a) preparing a semiconductor pellet including bump electrodes of first material and a circuit board including a conductive pattern and pad electrodes laminated on certain areas of said conductive pattern and having layers of second material, said bump electrodes being torn off from a conductive wire so as to expose fresh first material, said pad electrodes being subjected to one of an ion radiation and an atom radiation so as to remove contaminants therefrom;
b) aligning said bump electrodes with said pad electrodes, respectively; and
c) pressing said bump electrodes against said pad electrodes under application of heat so as to bond said bump electrodes with said pad electrodes.

5. The process as set forth in claim 4, in which said bump electrodes are heated to a certain temperature lower than a melting point of said first material.

6. The process as set forth in claim 4, in which said bump electrodes are formed through the sub-steps of
a-1) preparing said conductive wire having a leading end,
a-2) bonding said leading end to conductive pads of said semiconductor pellet, and
a-3) pulling said conductive wire so as to tear off said conductive wire.

7. The process as set forth in claim 4, in which said semiconductor pellet and said circuit board are stored in non-oxidizing ambience between said step a) and said step b).

8. The process as set forth in claim 4, in which said first material and said second material are gold and nickel, respectively.

9. The process as set forth in claim 4, in which ultrasonic vibrations are applied between a boundary between each bump electrode and each pad electrode in said step c)

10. The process as set forth in claim 4, further comprising the step of d) filling adhesive synthetic resin between said semiconductor pellet and said circuit board so as to increase adhesion therebetween.
